(19) United States
(12) Patent Application Publication
(10) Pub. No.: US 2009/0295443 A1
(43) Pub. Date: Dec. 3, 2009

(54) System and Method For Modifying Signal Characteristics

(75) Inventors: Bernhard Ruf, Sauerlach (DE); Jan Boris Philipp, Munich (DE)

Correspondence Address: EDELL, SHAPIRO & FINNAN, LLC, 1901 RESEARCH BLVD., SUITE 400, ROCKVILLE, MD, 20850, US

(73) Assignee: QIMONDA AG, Munich (DE)

(21) Appl. No.: 12/131,960

(22) Filed: Jun. 3, 2008

(51) Int. Cl. H03K 5/12

(52) U.S. Cl. 327/170

(57) ABSTRACT

The present invention embodiments provide a system to modify signal characteristics to produce a desired signal. The system comprises a signal module to modify signal characteristics. The signal module includes at least one input to receive an input signal including a substantially rectangular signal and one or more control signals and an output to provide a substantially trapezoidal signal. A signal unit of the signal module adjusts characteristics of the substantially rectangular signal including leading and/or trailing edges of that signal in accordance with the one or more control signals to produce the substantially trapezoidal signal. The present invention embodiments further include a probe card and method to adjust signal characteristics as described above.

### BACKGROUND

1. Technical Field

The present invention embodiments pertain to signal modification. In particular, the present invention embodiments pertain to modifying signal characteristics to produce resulting signals compatible for a desired application.

2. Discussion of Related Art

Various devices may require signals of specific characteristics (e.g., format, type, shape, etc.) in order to operate or perform desired actions. For example, phase change Random Access Memory (PCRAM) is an emerging technology with respect to non-volatile memories. This technology is based on a programmable resistor structure (e.g., including a phase change material), commonly referred to as a phase change element (PCE), that is utilized to form a memory cell. The phase transition of a phase change element (PCE) is based on an amorphous-crystalline phase transition of the phase change material. This material is typically a chalcogenide (or chalcogenide-free) compound material (e.g., germanium, antimony and tellurium (GeSbTe) or germanium and antimony (GeSb)), where bit states are assigned to different phase states of the phase change element (PCE). These phase states differ significantly in electrical resistivity, thereby enabling a bit value (e.g., logic zero or one) stored within a memory cell to be determined by examining the resistance of the corresponding phase change element (PCE) of that cell. The phase states of the phase change element (PCE) are produced by a heating and cooling process controlled electrically by passing current through the phase change element (PCE), thereby resulting in ohmic heating. The storage of bit values within these types of memory cells requires certain signal pulses. For example, in order to store a high bit or logic one value within a memory cell (e.g., perform a set operation for a memory cell or transform the corresponding phase change element (PCE) from an amorphous to a crystalline state), a substantially trapezoidal pulse (i.e., a twenty nanosecond to two microsecond pulse with an amplitude between 0.30 and 3.8 volts) is sent through a cell resistor, thereby heating the phase change (PC) material above a crystallization temperature and lowering the material resistance. In order to store a low bit or logic zero value within the cell (e.g., perform a reset operation for the memory cell), a substantially rectangular high pulse with a short falling edge (i.e., a two nanosecond to one-hundred nanosecond pulse with an amplitude between 0.5 and 4.0 volts) is applied to the memory cell. This causes the phase change material to melt and enter the amorphous state during subsequent quench cooling, thereby increasing the material resistance.

However, the specific pulse shapes required to control the state of a phase change element (PCE) memory cell limits the ability to concurrently test numerous phase change (PC) memory devices and corresponding phase change element (PCE) memory cells in production since test equipment produce incompatible signals for controlling set operations of these types of cells.

### SUMMARY

The present invention embodiments provide a system to modify signal characteristics to produce a desired signal. The system comprises a signal module to modify signal characteristics. The signal module includes at least one input to receive an input signal including a substantially rectangular signal and one or more control signals and an output to provide a substantially trapezoidal signal. A signal unit of the signal module adjusts characteristics of the substantially rectangular signal including leading and/or trailing edges of that signal in accordance with the one or more control signals to produce the substantially trapezoidal signal. The present invention embodiments further include a probe card and method to adjust signal characteristics as described above.

The above and still further features of the present invention will become apparent upon consideration of the following detailed description of example embodiments thereof, particularly when taken in conjunction with the accompanying drawings wherein like reference numerals in the various figures are utilized to designate like components.

### BRIEF DESCRIPTION OF THE DRAWINGS

FIG. 1 is block diagram of a signal module according to an embodiment of the present invention.

FIG. 2 is a block diagram of an example memory test arrangement for testing phase change (PC) memory devices and corresponding phase change element (PCE) memory cells.

FIG. 3 is a block diagram of an example memory test arrangement employed by an embodiment of the present invention.

FIG. 4A is an example electrical schematic diagram of the signal module of FIG. 3 according to an embodiment of the present invention.

FIG. 4B is a diagram of example resulting signals produced by the signal module of FIG. 4A based on input signals.

FIGS. 4C-4D are example timing diagrams illustrating inputs and the corresponding outputs produced by the signal module of FIG. 4A for respective reset and set operations.

FIG. 5A is an example electrical schematic diagram of the signal module of FIG. 3 according to another embodiment of the present invention.

FIGS. 5B-5C are example timing diagrams illustrating inputs and the corresponding outputs produced by the signal module of FIG. 5A for respective reset and set operations.

FIG. 6 is a procedural flow chart illustrating the manner in which signal characteristics are modified according to an embodiment of the present invention.

### DETAILED DESCRIPTION OF EXAMPLE EMBODIMENTS

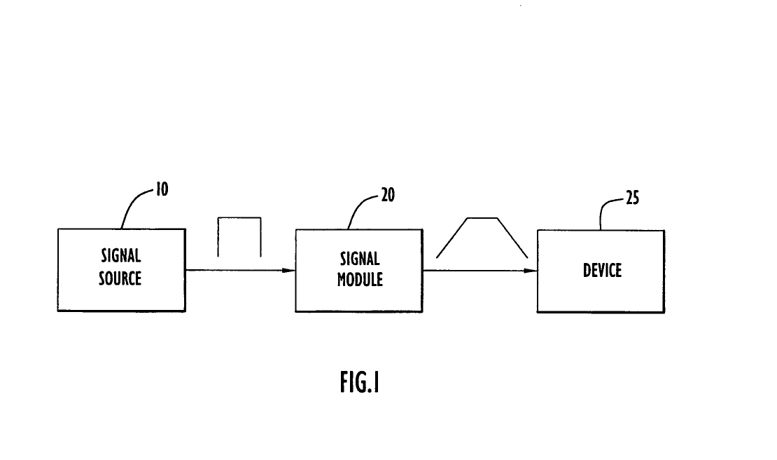

The present invention embodiments pertain to adjustment of signal characteristics for compatibility with a particular application and/or device. A signal module according to an embodiment of the present invention is illustrated in FIG. 1. Specifically, a signal source 10 produces a signal for transference to a device 25. Device 25 may include any conventional or other device (e.g., memory cell, processor, circuit element, etc.) responsive to a certain type of signal. The signal source may be implemented by any suitable signal generator (e.g., test equipment, processor, oscillator, etc.) and provides a signal and appropriate controls to a signal module 20. The signal module adjusts the characteristics of the signal received from signal source 10 in accordance with the controls and provides a resulting signal to device 25 in a form compatible with that device. By way of example, device 25 may be responsive to a substantially trapezoidal pulse, while signal source 10 is capable of producing substantially rectangular pulses. Signal module 20 receives a substantially rectangular pulse from the signal source and adjusts the signal characteristics according to the controls to produce a substantially trapezoidal pulse for device 25. For example, the signal module may alter the leading and/or trailing edges of the rectangular pulse in order to produce the desired trapezoidal pulse for device 25.

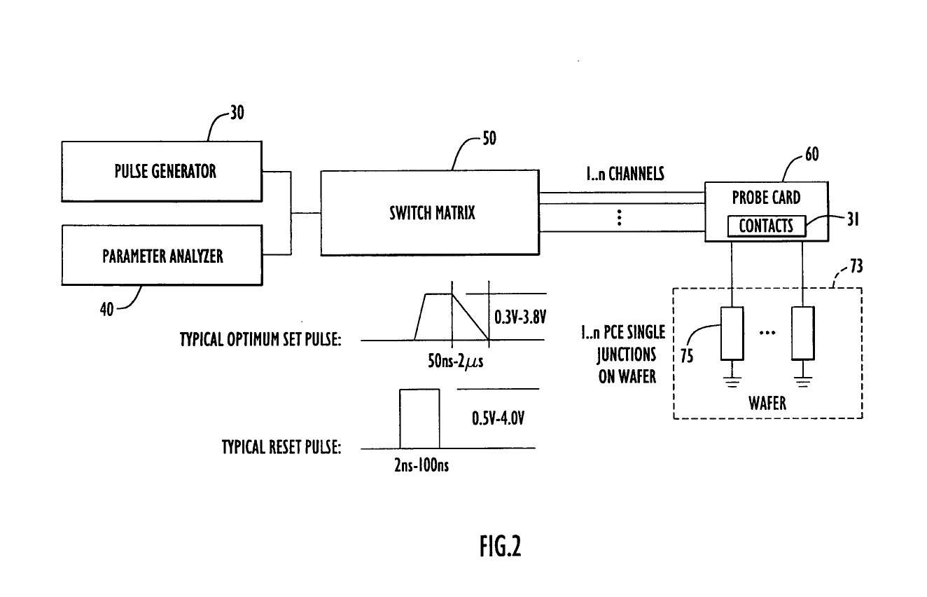

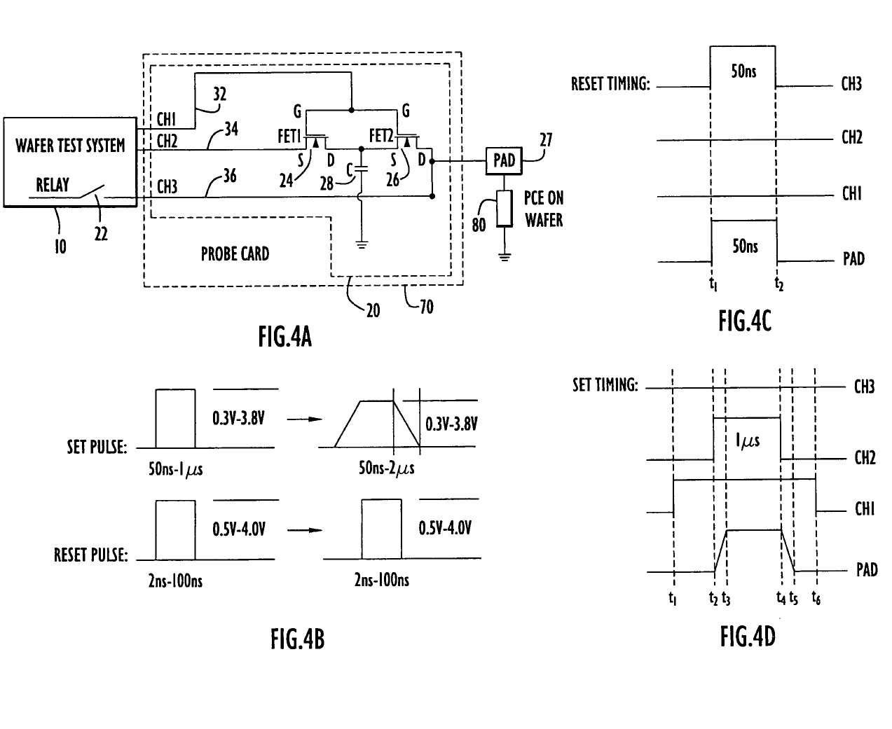

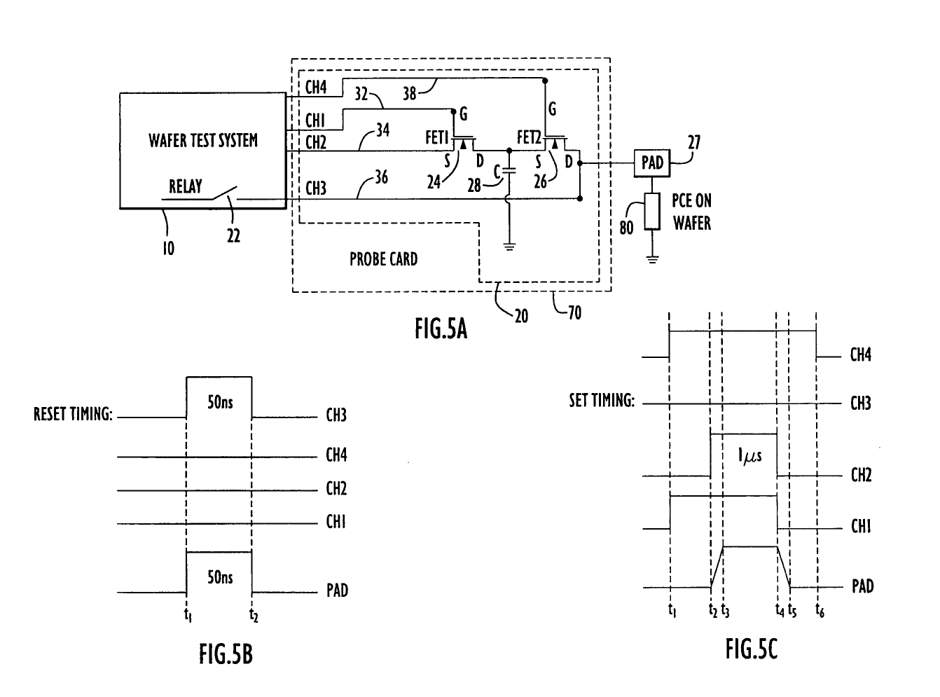

An example application for the signal module pertains to testing of phase change element (PCE) memory cells. An example test arrangement for testing phase change (PC) memory devices each with phase change element (PCE) memory cells on a wafer is illustrated in FIG. 2. Initially, a wafer 73 may include one or more phase change (PC) memory devices or chips 75 each with one or more phase change element (PCE) memory cells 80 (FIGS. 4A and 5A). The memory devices each include a set of pads or pins 27 (FIGS. 4A and 5A) to receive external signals and enable access of those signals by the memory cells. Specifically, the arrangement includes a pulse generator 30, a parameter analyzer 40, a switch matrix 50, a probe card 60 and phase change element (PCE) memory devices 75 on the wafer. The memory devices may be of any quantity, may include any quantity of memory cells, and may be implemented by any conventional or other phase change memory devices with a phase change material for the memory cells. The memory cells are typically responsive to a substantially trapezoidal pulse (e.g., twenty nanosecond to two microsecond pulse with an amplitude between 0.30 and 3.8 volts) to store a high bit or logic one value (e.g., perform a set operation) and a substantially rectangular high pulse with a short falling edge (e.g., a two nanosecond to one-hundred nanosecond pulse with an amplitude between 0.5 and 4.0 volts) to store a low bit or logic zero value (e.g., perform a reset operation).

Pulse generator 30 may be implemented by any conventional or other pulse generator (e.g., Agilent Model 81110, etc.) and provides the appropriate pulses to set and reset memory cells of memory devices 75. Parameter analyzer 40 may be implemented by any conventional or other device (e.g., Agilent Model 4156C, etc.) and measures direct current (DC) characteristics (e.g., the threshold voltage and the resistance after the set or reset pulses) of the phase change elements (PCEs) within memory devices 75. Switch matrix 50 may be implemented by any conventional or other switching device (e.g., Keithley Model 7173-50 or K707, etc.) and is coupled to the signal generator and parameter analyzer. The switching matrix multiplexes channels of the pulse generator and parameter analyzer to probe card 60 for transference of channel signals with phase change (PC) memory devices 75. Probe card 60 includes a series of contact sets 31 for interfacing memory devices 75 on the wafer (and the corresponding memory cells) via pads 27. The probe card may include any suitable quantity of contact sets and enables transfer of signals with the memory devices. The probe card may be implemented by any conventional or other module accessing the memory devices.

This testing arrangement provides a flexible pulse shape, thereby enabling a universal optimum pulse shape (e.g., a substantially trapezoidal pulse as described above) to be produced to set the memory cells of memory devices 75. However, the arrangement has long test times and is not compatible with automatic test equipment (ATE) since this equipment produces rectangular pulses incompatible to set the memory cells, thereby rendering the arrangement unusable for production testing.

The signal module of the present invention embodiments enables parallel testing of phase change (PC) memory devices with automatic test equipment for production testing. This reduces the test time dramatically compared to the test times for the test arrangement described above. The signal module receives rectangular pulses from the automatic test equipment and provides the proper set and reset waveforms for the phase change elements (PCEs) of the memory devices.

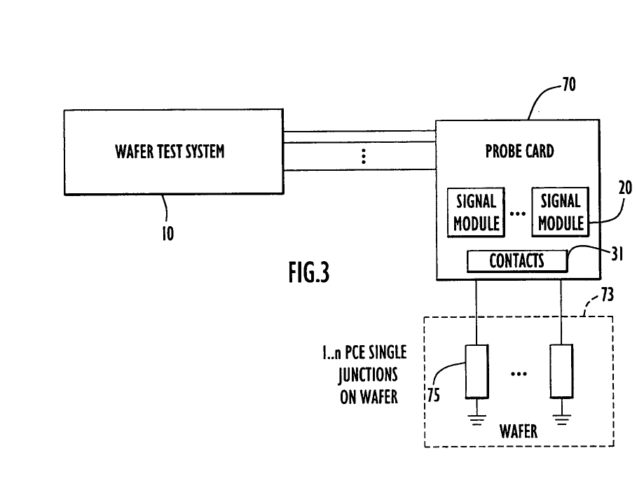

An example test arrangement for testing phase change (PC) memory devices on a wafer and employing a probe card with the signal module according to an embodiment of the present invention is illustrated in FIG. 3. Initially, wafer 73 may include one or more phase change (PC) memory devices 75 each with one or more phase change element (PCE) memory cells 80 (FIGS. 4A and 5A) as described above. The memory devices each include pads or pins 27 (FIGS. 4A and 5A) to receive external signals and to enable access of those signals by memory cells 80. Specifically, the arrangement includes signal source 10 in the form of a wafer test system, a probe card 70 and one or more phase change (PC) memory devices 75. The memory devices may be of any quantity, may include any quantity of memory cells and may be implemented by any conventional or other memory devices employing a phase change material as described above. Memory cells 80 are typically responsive to a substantially trapezoidal pulse (e.g., a twenty nanosecond to two microsecond pulse with an amplitude between 0.30 and 3.8 volts) to store a high bit or logic one value (e.g., perform a set operation) and a substantially rectangular high pulse with a short falling edge (e.g., a two nanosecond to one-hundred nanosecond pulse between 0.5 and 4.0 volts) to store a low bit or logic zero value (e.g., perform a reset operation) as described above.

Wafer test system 10 may be implemented by any conventional or other automatic test equipment (ATE) (e.g., Adventest Models T5365P, T5571P, T5375 or T5377, or equivalents thereof). The wafer test system provides signals to probe card 70 and performs direct current (DC) characterization (e.g., measures the threshold voltage and the resistance after the set or reset pulses). The wafer test system provides short test times since testing of memory devices 75 (and corresponding memory cells 80) may be performed in parallel. For example, wafer test system 10 may provide pulses concurrently on a maximum of 3,172 channels (e.g., for an Adventest Model T5377), thereby enabling this equipment to be used for production testing.

However, wafer test system 10 produces substantially rectangular pulses for directing set (e.g., a fifty nanosecond to one microsecond pulse with an amplitude between 0.30 and 3.8 volts) and reset (e.g., a two nanosecond to one-hundred nanosecond pulse with an amplitude between 0.5 and 4.0 volts) operations of the memory cells. Although these reset pulses are sufficient to enable storage of a low bit value in memory cells 80 (e.g., perform the reset operation), the memory cells are not responsive to the set pulses to store a high bit value (e.g., perform the set operation) due to the short duration (of the falling or trailing edge) of the set pulse.

Accordingly, signal module 20 is employed within the testing arrangement to provide the appropriate signals to memory devices 75 to perform set and reset operations on memory cells 80. In particular, probe card 70 is coupled to wafer test system 10, and includes contact sets 31 for interfacing memory devices 75 on the wafer (and corresponding pads 27 and memory cells 80 of those memory devices). The probe card may include any suitable quantity of contact sets and enables transfer of signals with the memory devices. The probe card is coupled to memory devices 75 via contacts 31 and pads 27 and receives signals from wafer test system 10. The probe card includes one or more signal modules 20 in order to process signals received from the wafer test system and provide appropriate signals to corresponding memory devices 75 (and associated pads 27 and memory cells 80) for set (e.g., storing a high bit value) and reset (e.g., storing a low bit value) operations.

Each signal module 20 is associated with a corresponding memory device 75 (and pad 27 and associated memory cells 80 coupled to that pad). In other words, signal module 20 adjusts characteristics of the set pulses received from wafer test system 10 for compatibility with memory cells 80 of a corresponding memory device 75 to enable the memory cells to perform a set operation. The reset pulses from the wafer system are forwarded to the corresponding memory device (and pad 27 and associated memory cells 80) in their received state (since these pulses are sufficient to enable the memory cells to perform the reset operation). The signal module enables the use of automatic test equipment (ATE) for testing of phase change element (PCE) memory cells, thereby providing short test times due to the ability to test phase change (PC) memory devices in parallel.

An example signal module according to an embodiment of the present invention is illustrated in FIGS. 4A-4B. Specifically, signal module 20 of probe card 70 is coupled to wafer test system 10 via lines 32 (e.g., “Ch1” as viewed in FIG. 4A), 34 (e.g., “Ch2” as viewed in FIG. 4A) and 36 (e.g., “Ch3” as viewed in FIG. 4A), and receives various control or other signals on those lines from the wafer test system to produce the appropriate signals for a corresponding memory device 75 (and pad 27 and one or more memory cells 80 of that memory device). The wafer test system includes a relay 22 to provide a reset signal on line 36 (Ch3). The relay may be implemented by any conventional or other relay or switching device. Signal module 20 is coupled to a corresponding memory device pad 27 (via contacts 31) to provide the resulting signal to that pad and one or more associated memory cells 80.

Signal module 20 includes transistors 24, 26 and a capacitor 28. The transistors may be implemented by n-channel type Field Effect Transistors (FET). However, any conventional or other transistors may be utilized. Capacitor 28 may similarly be implemented by any conventional or other capacitors or capacitive devices. Each transistor 24, 26 includes a gate G, a source S and a drain D. The gates of transistors 24, 26 are connected together and coupled to line 32 (Ch1) receiving signals from wafer test system 10. The source (S) of transistor 24 is coupled to line 34 (Ch2) receiving signals from the wafer test system, while the drain (D) of transistor 24 is coupled to the source (S) of transistor 26. The drain (D) of transistor 26 is coupled to a corresponding pad 27, and to wafer test system 10 via line 36 (Ch3). Capacitor 28 is disposed between a ground potential and the junction between the drain (D) of transistor 24 and the source (S) of transistor 26.

Referring to FIG. 4B, signal module 20 receives a substantially rectangular reset signal (e.g., a two nanosecond to one-hundred nanosecond pulse with an amplitude between 0.5 and 4.0 volts) on line 36 (Ch3) and forwards this signal to a corresponding memory device pad 27 (unmodified) to enable one or more memory cells 80 to perform a reset operation (e.g., store a low bit or logic zero value). With respect to a set operation, the signal module receives a substantially rectangular set signal (e.g., a fifty nanosecond to one microsecond pulse with an amplitude between 0.30 and 0.38 volts) on line 34 (Ch2) and produces a substantially trapezoidal signal (e.g., a pulse with a fifty nanosecond to two microsecond trailing edge and an amplitude between 0.30 and 3.8 volts) for pad 27 sufficient to enable one or more memory cells 80 to perform a set operation (e.g., store a high bit or logic one value).

Operation of the signal module of FIG. 4A to produce signals enabling reset and set operations of memory cells 80 is described. By way of example, wafer test system 10 provides control or other signals on lines 32 (Ch1), 34 (Ch2) and 36 (Ch3) to produce signals enabling a reset operation of memory cells 80 as illustrated in FIG. 4C. These signals are each initially set to a logic zero or low value (e.g., at or near ground potential), where relay 22 is in a closed state. The low value signal on line 32 (Ch1) is provided to the coupled gates (G) of transistors 24, 26, while the low value signal on line 34 (Ch2) is provided to the source (S) of transistor 24. These low value signals provide transistors 24, 26 in a high ohmic state (e.g., cutoff), thereby effectively disabling capacitor 28 and resulting in a logic zero or low value signal at pad 27.

At a time t₁, wafer test system 10 provides a substantially rectangular pulse or reset signal (e.g., fifty nanosecond pulse with a rising edge at time t₁ and a falling edge at time t₂) on line 36 (Ch3), while lines 32 (Ch1) and 34 (Ch2) each further receive the logic zero or low value signals (e.g., at or near ground potential). The low value signals on lines 32 (Ch1) and 34 (Ch2) provide transistors 24, 26 in a high ohmic state (e.g., cutoff) as described above. In this case, transistor 26 effectively decouples capacitor 28, and the pulse on line 36 (Ch3) is provided to pad 27. Thus, the pulse or reset signal from wafer test system 10 to enable one or more corresponding memory cells 80 to perform a reset operation is basically directly transferred (unmodified) to memory device pad 27 (and subsequently to one or more memory cells 80).

Operation of the signal module of FIG. 4A to produce signals enabling set operations of memory cells 80 is described. By way of example, wafer test system 10 provides control or other signals on lines 32 (Ch1), 34 (Ch2) and 36 (Ch3) to produce signals enabling a set operation of memory cells 80 as illustrated in FIG. 4D. These signals are each initially set to logic zero or low values (e.g., at or near ground potential). The low value signal on line 32 (Ch1) is provided to the coupled gates (G) of transistors 24, 26, while the low value signal on line 34 (Ch2) is provided to the source (S) of transistor 24. These low value signals provide transistors 24, 26 in a high ohmic state (e.g., cutoff) as described above, thereby effectively disabling capacitor 28 and resulting in a logic zero or low value signal at corresponding memory device pad 27. Relay 22 which controls line 36 (Ch3) is in an open state. The relay stays in this open state during the whole set operation described below. Therefore, line 36 (Ch3) acts only as a passive element in this case.

At a time t₁, wafer test system 10 provides a substantially rectangular pulse (e.g., with a rising edge at time t₁ and a falling edge at time t₆) on line 32 (Ch1), while line 34 (Ch2) further receives the logic zero or low value signal (e.g., at or near ground potential). The pulse on line 32 (Ch1) is provided to the gates (G) of transistors 24, 26 enabling the transistors to subsequently enter an active state. The resistance of the transistors may be controlled based on the amplitude of the voltage provided to the gates (G) of those transistors. The wafer test system further provides a substantially rectangular pulse or set signal (e.g., one microsecond pulse with a rising edge at time t₂ and a falling edge at time t₄) on line 34 (Ch2) at time t₂, while line 32 (Ch1) maintains the received pulse.

The active or conducting transistors enable capacitor 28 to charge based on the pulse or set signal on line 34 (Ch2). The capacitor charges to the amplitude level of that pulse signal in accordance with a time constant derived from the resistance of transistor 24 and capacitance of capacitor 28. The delay for capacitor 28 to charge results in the upward ramp formed for the rising or leading edge of the resulting signal (e.g., between times t₂ and t₃) at pad 27. When the capacitor is fully charged, the resulting signal at the pad includes substantially the same amplitude as the pulse on line 34 (Ch2).

At time t₄, the falling edge of the pulse on line 34 (Ch2) enables capacitor 28 to discharge. The capacitor discharges to a voltage at or near ground potential in accordance with a time constant derived from the resistance of transistor 24 and capacitance of capacitor 28. The delay for capacitor 28 to discharge results in the downward ramp formed for the falling or trailing edge of the resulting signal (e.g., between times t₄ and t₅) at pad 27. The pulse on line 32 (Ch1) includes a duration (e.g., from time t₁ to time t₆) sufficient to maintain the gate voltage of transistors 24, 26 during the time interval of the resulting signal at pad 27 (e.g., through the charging and discharging of capacitor 28 to form the resulting pulse at pad 27).

The resulting substantially trapezoidal signal at pad 27 includes non-linear leading and trailing edges based on the charging and discharging of capacitor 28 (in accordance with the time constant) as described above, and is suitable to enable one or more corresponding memory cells 80 to perform a set operation. Since the gates of transistors 24, 26 are connected together, capacitor 28 charges and discharges based on a common time constant (e.g., derived from the resistance of transistor 24 and the capacitance of capacitor 28) with the resulting signal including symmetrical leading and trailing edges. By way of example, transistor 24 may include a resistance of 1 Kilo Ohms in an active or on state, transistor 26 may include a resistance of 500 Ohms (or as low as possible) in an active or on state, and capacitor 28 may include a capacitance of 500 pico Farads, thereby providing a time constant of approximately 500 nanoseconds (for charging and discharging of capacitor 28). However, the transistors and capacitor may include any suitable characteristics (e.g., resistance, capacitance, etc.) to attain any desired shape or waveform for the resulting signal at pad 27.

An example signal module according to another embodiment of the present invention is illustrated in FIG. 5A. Initially, the signal module and corresponding test arrangement are substantially similar to the signal module and arrangement described above for FIG. 4A, and further enable independent control of the transistor gate voltages (and the resistance of the transistors) as described below. This enables the leading and trailing edges of the resulting signal at a corresponding memory device pad 27 to be individually controlled (e.g., asymmetrical). Specifically, signal module 20 of probe card 70 is coupled to wafer test system 10 via lines 32 (e.g., “Ch1” as viewed in FIG. 5A), 34 (e.g., “Ch2” as viewed in FIG. 5A), and 36 (e.g., “Ch3” as viewed in FIG. 5A), each as described above. The signal module is further coupled to the wafer test system via a line 38 (e.g., “Ch4” as viewed in FIG. 5A). Signal module 20 receives various control or other signals on those lines from the wafer test system to produce the appropriate signals for a corresponding memory device 75 (and pad 27 and one or more memory cells 80 of that memory device). The wafer test system includes relay 22 to provide a signal on line 36 (Ch3) as described above. The relay may be implemented by any conventional or other relay or switching device. Signal module 20 is coupled to a corresponding memory device pad 27 (via contacts 31) to provide the resulting signal to that pad and one or more associated memory cells 80.

Signal module 20 includes transistors 24, 26 and a capacitor 28, each substantially similar to those described above. The transistors may be implemented by n-channel type Field Effect Transistors (FET). However, any conventional or other transistors may be utilized. Capacitor 28 may similarly be implemented by any conventional or other capacitors or capacitive devices as described above. Each transistor 24, 26 includes a gate G, a source S and a drain D. The gate of transistor 24 is coupled to line 32 (Ch1), while the gate (G) of transistor 26 is coupled to line 38 (Ch4) with each of these lines receiving signals from wafer test system 10. The source (S) of transistor 24 is coupled to line 34 (Ch2) receiving signals from the wafer test system, while the drain (D) of transistor 24 is coupled to the source (S) of transistor 26 as described above. The drain (D) of transistor 26 is coupled to a corresponding pad 27, and to wafer test system 10 via line 36 (Ch3) as described above. Capacitor 28 is disposed between a ground potential and the junction between the drain (D) of transistor 24 and the source (S) of transistor 26.

Signal module 20 receives a substantially rectangular reset signal (e.g., a two nanosecond to one-hundred nanosecond pulse with an amplitude between 0.5 and 4.0 volts) on line 36 (Ch3) and forwards this signal to a corresponding memory device pad 27 (unmodified) to enable one or more memory cells 80 to perform a reset operation (e.g., store a low bit or logic zero value). With respect to a set operation, the signal module receives a substantially rectangular set signal (e.g., a fifty nanosecond to one microsecond pulse with an amplitude between 0.30 and 3.8 volts) on line 34 (Ch2) and produces a resulting substantially trapezoidal signal with modified (e.g., non-linear, ramping, etc.) leading and trailing edges for pad 27 sufficient to enable one or more memory cells 80 to perform a set operation (e.g., store a high bit or logic one value).

Operation of the signal module of FIG. 5A to produce signals enabling reset and set operations of memory cells 80 is described. By way of example, wafer test system 10 provides control signals on lines 32 (Ch1), 34 (Ch2), 36 (Ch3) and 38 (Ch4) to produce signals enabling a reset operation of one or more corresponding memory cells 80 as illustrated in FIG. 5B. These signals are each initially set to logic zero or low values (e.g., at or near ground potential), where relay 22 is in a closed state. The low value signal on line 32 (Ch1) is provided to the gate (G) of transistor 24, while the low value signal on line 38 (Ch4) is provided to the gate (G) of transistor 26. The low value signal on line 34 (Ch2) is provided to the source (S) of transistor 24. These low value signals provide transistors 24, 26 in a high ohmic state (e.g., cutoff), thereby effectively disabling capacitor 28 and resulting in a logic zero or low value signal at pad 27.

At a time t₁, wafer test system 10 provides a substantially rectangular pulse or reset signal (e.g., fifty nanosecond pulse with a rising edge at time t₁ and a falling edge at time t₂) on line 36 (Ch3), while lines 32 (Ch1), 34 (Ch2) and 38 (Ch4) each further receive the low value signals (e.g., at or near ground potential). The low value signals on lines 32 (Ch1), 34 (Ch2) and 38 (Ch4) provide transistors 24, 26 in a high ohmic state (e.g., cutoff) as described above. In this case, transistor 26 effectively decouples capacitor 28, and the reset signal or pulse on line 36 (Ch3) is provided to corresponding memory device pad 27. Thus, the reset signal from wafer test system 10 to enable one or more memory cells 80 to perform a reset operation is basically directly transferred (unmodified) to pad 27 (and subsequently to one or more corresponding memory cells 80).

Operation of the signal module of FIG. 5A to produce signals enabling set operations of memory cells 80 is described. By way of example, wafer test system 10 provides control signals on lines 32 (Ch1), 34 (Ch2), 36 (Ch3) and 38 (Ch4) to produce signals enabling a set operation of memory cells 80 as illustrated in FIG. 5C. These signals are each initially set to logic zero or low values (e.g., at or near ground potential). The low value signal on line 32 (Ch1) is provided to the gate (G) of transistor 24, while the low value signal on line 38 (Ch4) is provided to the gate (G) of transistor 26. The low value signal on line 34 (Ch2) is provided to the source (S) of transistor 24. These low value signals provide transistors 24, 26 in a high ohmic state (e.g., cutoff) as described above, thereby effectively disabling capacitor 28 and resulting in a logic zero or low value signal at corresponding memory device pad 27. Relay 22 which controls line 36 (Ch3) is in an open state. The relay stays in this open state during the whole set operation described below. Therefore, line 36 (Ch3) acts only as a passive element in this case.

At a time t₁, wafer test system 10 provides a substantially rectangular pulse (e.g., with a rising edge at time t₁ and a falling edge at time t₄) on line 32 (Ch1), and a substantially rectangular pulse (e.g., with a rising edge at time t₁ and a falling edge at time t₆) on line 38 (Ch4). Line 34 (Ch2) further receives the logic zero or low value signals (e.g., at or near ground potential). The pulses on lines 32 (Ch1) and 38 (Ch4) are provided to the gates (G) of transistors 24, 26 enabling the transistors to subsequently enter an active state. The resistance of the transistors may be controlled based on the amplitude of the voltages provided to the gates (G) of those transistors. The wafer test system further provides a substantially rectangular pulse or set signal (e.g., one microsecond pulse with a rising edge at time t₂ and a falling edge at time t₄) on line 34 (Ch2) at time t₂, while lines 32 (Ch1) and 38 (Ch4) maintain the received pulses.

The active or conducting transistors enable capacitor 28 to charge based on the pulse or set signal on line 34 (Ch2). The capacitor charges to the amplitude level of that pulse in accordance with a time constant derived from the resistance of transistor 24 and capacitance of capacitor 28. The delay for capacitor 28 to charge results in the upward ramp formed for the rising or leading edge of the resulting signal (e.g., between times t₂ and t₃) at pad 27. When the capacitor is fully charged, the resulting signal at the pad includes substantially the same amplitude as the pulse on line 34 (Ch2). Since the gate voltage of transistor 24 may be controlled independently of the gate voltage of transistor 26, the upward ramp or leading edge of the resulting signal at pad 27 may be controlled (without affecting the trailing edge of that signal).

At a time t₄, the trailing or falling edges of the pulses or signals on lines 32 (Ch1) and 34 (Ch2) enable capacitor 28 to discharge. The falling edge of the pulse on line 32 (Ch1) effectively disables transistor 24, and enables the capacitor to discharge based on transistor 26 that is still enabled by the pulse or gate voltage from line 38 (Ch4). The capacitor discharges to a voltage at or near ground potential in accordance with a time constant derived from the resistance of transistor 26, the resistance of the phase change elements (PCEs) of one or more memory cells 80 and the capacitance of capacitor 28. The delay for capacitor 28 to discharge results in the downward ramp formed for the falling or trailing edge of the resulting signal (e.g., between times t₄ and time t₅) at pad 27. The pulse on line 32 (Ch1) includes a duration (e.g., from time t₁ to time t₄) sufficient to maintain the gate voltage of transistor 24 during the time interval prior to the falling edge of the resulting signal at pad 27 (e.g., through the charging of capacitor 28), while the pulse on line 38 (Ch4) includes a duration (e.g., from time t₁ to time t₆) sufficient to maintain the gate voltage of transistor 26 during the time interval of the resulting signal at pad 27 (e.g., through the charging and discharging of capacitor 28 to form the resulting pulse at pad 27). Since the gate voltage of transistor 24 may be controlled independently of the gate voltage of transistor 26, the upward and downward ramps of the respective leading and trailing edges of the resulting signal at pad 27 may be controlled independently.

The resulting substantially trapezoidal signal at pad 27 includes non-linear leading and trailing edges based on the charging and discharging of capacitor 28 (in accordance with the time constants) as described above, and is suitable to enable one or more corresponding memory cells 80 to perform a set operation. Thus, the leading and trailing edges of the resulting signal at pad 27 may be individually controlled (e.g., may be asymmetrical, where the resistance of transistor 24 controls the leading edge of the resulting signal, while the resistance of transistor 26 (and the resistance of the corresponding phase change elements (PCEs) of memory cells 80) controls the trailing edge of the resulting signal). The transistors and capacitor may include any suitable characteristics (e.g., resistance, capacitance, etc.) to attain any desired shape or waveform for the resulting signal at pad 27.

This embodiment enables a reduced number of memory devices 75 to be tested in parallel relative to the embodiment described above (since an additional channel of wafer test system 10 is utilized for testing (e.g., Ch4)). However, the embodiment provides greater flexibility with respect to the shape of the resulting signal at pad 27, and a significant quantity of memory devices may be concurrently tested, thereby enabling the embodiment to be utilized for production testing.

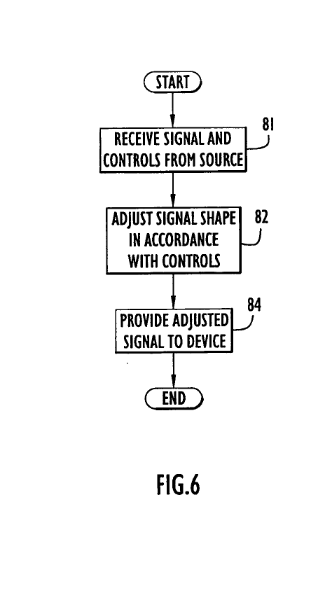

Operation of the present invention embodiments is described with reference to FIG. 6. Initially, the adjustment of signal characteristics may be performed on any suitable device (e.g., probe card, intermediate device, end device, signal generator, etc.) to provide desired signals for an application and/or device. Specifically, a signal and corresponding controls from a suitable signal source are received at 81. The signal source may be implemented by any suitable signal generator (e.g., test equipment, processor, oscillator, etc.). The characteristics of the received signal are adjusted in accordance with the controls to generate a resulting signal with desired characteristics at 82. By way of example, the leading and/or trailing edges of the signal may be modified (e.g., ramp, non-linear, etc.) as described above to provide a resulting signal in a desired format. However, any other signal characteristics may be modified (e.g., pulse width, frequency, etc.). The resulting signal is provided to a target device in an appropriate format at 84.

It will be appreciated that the embodiments described above and illustrated in the drawings represent only a few of the many ways of implementing a system and method for modifying signal characteristics.

The present invention embodiments may be utilized to adjust any characteristics (e.g., shape, pulsewidth, frequency, leading and/or trailing edges, etc.) of any types of signals (e.g., pulses, sinusoidal signals, etc.). The present invention embodiments may receive any types of signals of any shapes (e.g., rectangular or triangular pulses, etc.) and produce any suitable waveforms (e.g., rectangular, trapezoidal, triangular, an undulating, flat or pointed apex, etc.).

The signal module may be employed within any suitable existing device (e.g., test unit, probe card, memory or other end device, etc.) or external of that device. In the case where the signal module is employed within a device, the newly formed device forms an embodiment of the present invention (e.g., probe card, test unit, memory device, etc.). The signal module may be used for any operational applications (e.g., during normal or other operation of a device, testing, etc.) and to produce signals for any types of memories (e.g., phase change (PC), etc.) or other devices responsive to certain types of signals.

The signal module may receive any suitable input signal (e.g., an initial pulse or other signal for adjustment, etc.) and/or control signals (e.g., to indicate or control modification of signal characteristics) to generate a desired signal. These signals may be provided by any suitable devices (e.g., test unit, signal generator, oscillator, etc.). The signal module adjust characteristics of a provided signal, or generate a new signal with the desired characteristics.

Any quantity of signal modules may be utilized within a device (e.g., probe card, test unit, memory device, etc.). The signal module may produce signals for any quantity of devices (e.g., memory devices, etc.) or corresponding conductors (e.g., pad, etc.). The signal module may coupled to and utilize any suitable quantity of channels of a test system or other signal source. The test system may be implemented by any conventional or other testing system (e.g., ATE, etc.) for testing of any suitable memory or other devices, and may produce any types of pulses or signals. Alternatively, any quantity of signal modules may be employed by the test system at any desired locations (e.g., to form a new test system as an embodiment of the present invention).

The memory devices may be of any quantity or type, may be implemented by any conventional or other memory devices (e.g., PC memory devices, etc.), and may include any quantity of pads and memory cells at any desired locations. Alternatively, any quantity of signal modules may be employed by the memory devices at any desired locations (e.g., to form a new memory device as an embodiment of the present invention).

The probe card may include any quantity of any conventional or other probe card or interface components or devices (e.g., contact sets, conductors, etc.) to access the memory devices. Any quantity of signal modules may be disposed on the probe card at any desired locations (e.g., to form a new probe card as an embodiment of the present invention). The pads, contacts and lines may be of any quantity, size or shape, may be disposed in any suitable location or arrangement, and may be implemented by any conventional or other conductors. The wafer may include any quantity of memory or other devices at any suitable locations. The memory cells may employ any suitable phase change material with varying electrical or other properties to determine a logic state.

The signal module may be implemented by any quantity of any conventional or other circuitry, units or components (e.g., transistors, capacitors, digital signal processor, etc.). The transistors may be implemented by any quantity of any type of any conventional or other switching device (e.g., n or p channel transistors, MOSFET, BJT, etc.). The capacitor may be of any quantity, and may be implemented by any conventional or other devices with a capacitance characteristic (e.g., capacitor, etc.). The transistors and capacitor may include any suitable characteristic values (e.g., resistance, capacitance, etc.) to produce a desired signal. Further, additional circuit components may be utilized to provide desired characteristics (e.g., capacitors, resistors or other circuit components may be provided to attain a desired time constant, etc.). The relay may be implemented by any quantity of any conventional or other relay or switching device (e.g., electrical or mechanical relay or switch, etc.).

The transistors may be controlled collectively in any fashion to control signal characteristics (e.g., provide symmetrical characteristics). Alternatively, the transistors may be controlled individually in any fashion to control individual signal characteristics (e.g., provide symmetrical or asymmetrical signal characteristics, etc.).

The timing diagrams illustrated in the drawings represent example timings for the input and output signals. The signal module may provide any suitable timing to produce signals with any desired characteristics (e.g., leading and trailing edge ramps of any suitable duration, flat, undulating or pointed apex, etc.). The present invention embodiments may alternatively be implemented by any type of hardware and/or other processing circuitry. The processes described above and illustrated in the flow chart may be modified in any manner that accomplishes the functions described herein. In addition, the functions in the flow chart or description may be performed in any order that accomplishes a desired operation.

The present invention embodiments may be utilized for any suitable applications to provide desired signals where a signal source provides incompatible signals for an intended device (e.g., memory test and operation, communications, device or other interfaces, etc.). Further, the present invention embodiments may be utilized for testing of combinations of devices, where some of the devices are compatible with the signals from a signal source and others of the devices are not responsive to those types of signals (e.g., testing of combinations of phase change (PC) memory devices and other types of memory devices, etc.).

It is to be understood that the terms “leading”, “trailing”, “upward”, “downward”, “low”, “high” and the like are used herein merely to describe points of reference and do not limit the present invention to any particular configuration.

From the foregoing description, it will be appreciated that the invention makes available a novel system and method for modifying signal characteristics, wherein signal characteristics are modified to produce resulting signals compatible for a desired application.

Having described example embodiments of a new and improved system and method for modifying signal characteristics, it is believed that other modifications, variations and changes will be suggested to those skilled in the art in view of the teachings set forth herein. It is therefore to be understood that all such variations, modifications and changes are believed to fall within the scope of the present invention as defined by the appended claims.

What is claimed is:

1. A system to modify signal characteristics to produce a desired signal comprising:
a signal module to modify signal characteristics and including:
at least one input to receive an input signal including a substantially rectangular signal and one or more control signals;
a signal unit to adjust characteristics of said substantially rectangular signal including leading and/or trailing edges of that signal in accordance with said one or more control signals to produce a substantially trapezoidal signal; and
an output to provide said substantially trapezoidal signal.

2. The system of claim 1, wherein said signal unit includes:
a plurality of transistors responsive to at least one of said control signals; and
a capacitor coupled to a junction between said plurality of transistors and responsive to said transistors for charging and discharging, wherein said charging of said capacitor controls formation of said leading edge of said substantially trapezoidal signal, and discharging of said capacitor controls formation of said trailing edge of said substantially trapezoidal signal.

3. The system of claim 2, wherein each transistor includes a gate and said gates of said plurality of transistors are coupled together to receive a common control signal, and wherein said transistors control charging and discharging of said capacitor to provide said substantially trapezoidal signal with symmetrical leading and trailing edges.

4. The system of claim 2, wherein each transistor includes a gate to receive a respective control signal, and wherein a first one of said transistors controls charging of said capacitor to control formation of said leading edge of said substantially trapezoidal signal, and a second one of said transistors controls discharging of said capacitor to independently control formation of said trailing edge of said substantially trapezoidal signal.

5. The system of claim 4, wherein said substantially trapezoidal signal includes asymmetrical leading and trailing edges.

6. The system of claim 1, further including:
at least one memory device unresponsive to said substantially rectangular signal to perform a particular memory operation;
a test unit to provide said substantially rectangular signal and said one or more control signals to test said at least one memory device; and
a probe card coupled to said test unit and housing said signal module to provide said substantially trapezoidal signal from said signal module to said at least one memory device in response to said substantially rectangular signal from said test unit, wherein said at least one memory device is responsive to said substantially trapezoidal signal to perform said particular memory operation.

7. The system of claim 6, wherein said at least one memory device includes a phase change memory device, and said particular memory device operation includes a set operation.

8. A system to interface at least one memory device comprising:
a probe card to transfer signals and including a signal module comprising:
at least one input to receive an input signal and one or more control signals, wherein said input signal includes a substantially rectangular signal;
a signal unit to adjust characteristics of said substantially rectangular signal including leading and/or trailing edges of that signal in accordance with said one or more control signals to produce a substantially trapezoidal signal; and
an output to provide said substantially trapezoidal signal.

9. The system of claim 8, wherein said signal unit includes:
a plurality of transistors responsive to at least one of said control signals; and
a capacitor coupled to a junction between said plurality of transistors and responsive to said transistors for charging and discharging, wherein said charging of said capacitor controls formation of said leading edge of said substantially trapezoidal signal, and discharging of said capacitor controls formation of said trailing edge of said substantially trapezoidal signal.

10. The system of claim 9, wherein each transistor includes a gate and said gates of said plurality of transistors are coupled together to receive a common control signal, and wherein said transistors control charging and discharging of said capacitor to provide said substantially trapezoidal signal with symmetrical leading and trailing edges.

11. The system of claim 9, wherein each transistor includes a gate to receive a respective control signal, and wherein a first one of said transistors controls charging of said capacitor to control formation of said leading edge of said substantially trapezoidal signal, and a second one of said transistors controls discharging of said capacitor to independently control formation of said trailing edge of said substantially trapezoidal signal.

12. The system of claim 11, wherein said substantially trapezoidal signal includes asymmetrical leading and trailing edges.

13. The system of claim 8, further including:
at least one phase change memory device unresponsive to said substantially rectangular signal to perform a memory set operation; and
a test unit to provide said substantially rectangular signal and said one or more control signals to said probe card to test said at least one phase change memory device;
wherein said probe card provides said substantially trapezoidal signal from said signal module to said at least one phase change memory device in response to said substantially rectangular signal from said test unit, wherein said at least one phase change memory device is responsive to said substantially trapezoidal signal to perform said set operation.

14. A system to modify signal characteristics to produce a desired signal comprising:
signal means for modifying signal characteristics and including:
at least one input means for receiving an input signal including a substantially rectangular signal and one or more control signals;
modify means for adjusting characteristics of said substantially rectangular signal including leading and/or trailing edges of that signal in accordance with said one or more control signals to produce a substantially trapezoidal signal; and
output means for providing said substantially trapezoidal signal.

15. The system of claim 14, wherein said modify means includes:
a plurality of switching means responsive to at least one of said control signals for forming said substantially trapezoidal signal; and
charging means coupled to a junction between said plurality of switching means and responsive to said switching means for charging and discharging, wherein said charging of said charging means controls formation of said leading edge of said substantially trapezoidal signal, and discharging of said charging means controls formation of said trailing edge of said substantially trapezoidal signal.

16. The system of claim 15, wherein each switching means includes a trigger means for activating that switching means and said trigger means of said plurality of switching means are coupled together to receive a common control signal, and wherein said switching means control charging and discharging of said charging means to provide said substantially trapezoidal signal with symmetrical leading and trailing edges.

17. The system of claim 15, wherein each switching means includes a trigger means for activating that switching means in response to a respective control signal, and wherein a first one of said switching means controls charging of said charging means to control formation of said leading edge of said substantially trapezoidal signal, and a second one of said switching means controls discharging of said charging means to independently control formation of said trailing edge of said substantially trapezoidal signal.

18. The system of claim 14, further including:
at least one phase change memory device unresponsive to said substantially rectangular signal to perform a memory set operation;
test means for providing said substantially rectangular signal and said one or more control signals to test said at least one phase change memory device; and
probe means coupled to said test means and housing said signal means for providing said substantially trapezoidal signal from said signal means to said at least one phase change memory device in response to said substantially rectangular signal from said test means, wherein said at least one phase change memory device is responsive to said substantially trapezoidal signal to perform said set operation.

19. A method of modifying signal characteristics to produce a desired signal comprising:
receiving an input signal including a substantially rectangular signal and one or more control signals; and
adjusting characteristics of said substantially rectangular signal including leading and/or trailing edges of that signal in accordance with said one or more control signals to produce a substantially trapezoidal signal.

20. The method of claim 19, wherein said adjusting includes:
controlling charging of a charge device to control formation of said leading edge of said substantially trapezoidal signal; and
controlling discharging of said charge device to control formation of said trailing edge of said substantially trapezoidal signal.

21. The method of claim 20, wherein said charging and discharging of said charge device are performed in accordance with a common control signal to provide said substantially trapezoidal signal with symmetrical leading and trailing edges.

22. The method of claim 20, wherein said charging and discharging of said charge device are performed in accordance with respective control signals, and wherein said controlling charging of said charge device controls formation of said leading edge of said substantially trapezoidal signal, and said controlling discharging of said charge device independently controls formation of said trailing edge of said substantially trapezoidal signal.

23. The method of claim 19, further including:
receiving said substantially rectangular signal and said one or more control signals from a test unit to test at least one phase change memory device unresponsive to said substantially rectangular signal to perform a memory set operation; and
providing said substantially trapezoidal signal to said at least one phase change memory device in response to said substantially rectangular signal from said test unit, wherein said at least one phase change memory device is responsive to said substantially trapezoidal signal to perform said set operation.
